(19) United States
(12) Patent Application Publication
(10) Pub. No.: US 2026/0316228 A1
(43) Pub. Date: Oct. 15, 2026

(54) PIPE WRENCH

(71) Applicant: MATATAKITOYO TOOL CO., LTD., Taichung City (TW)

(72) Inventor: Yi-Min WU, Taichung City (TW)

(21) Appl. No.: 19/568,658

(22) Filed: Mar. 16, 2026

(30) Foreign Application Priority Data
Apr. 9, 2025 (TW) 114113421

(51) Int. Cl. B25B 13/50

(52) U.S. Cl. CPC B25B 13/505

(57) ABSTRACT

A pipe wrench including a lower jaw, an upper jaw, a pivot shaft, and a spring. The lower jaw includes a handle section and a lower clamping section. A slot and an outer pivot hole are defined on the lower clamping section. The lower clamping section includes a lower clamping arcuate surface and inclined arcuate surfaces. The upper jaw includes a pivot section and an upper clamping section. The upper clamping section includes an opening, an upper clamping arcuate surface, pawl teeth, a stop surface, and a clearance space. The pivot shaft is inserted in the outer pivot hole and the pivot section. The spring is disposed in the slot and elastically abuts against the stop plate.

### BACKGROUND OF THE DISCLOSURE

### Technical Field

The technical field relates to a wrench, and particularly to a pipe wrench.

### Description of Related Art

A pipe wrench is a tool used for installing and removing pipe fittings. The main body of the pipe wrench includes a head with an open-type clamping mouth. Two sides of the clamping mouth respectively serve as two clamping portions and are configured to grip a nut and apply torque. The two clamping portions form a three-surface clamping interface that engages with the six sides of the nut, thereby securing the nut in place. The two clamping portions drive the nut to rotate by rotating the wrench. Thus, the tightening or loosening of the nut is achieved depending on the direction of rotation.

Pipe wrenches of the related art typically require a sufficient rotation angle of the handle to achieve effective torque output during operation. However, when the user operates in a confined space, for example, near a wall, mechanical equipment, or other obstructions, the rotatable angle of the handle is severely limited. As a result, the user is unable to perform continuous rotational operations and must frequently release the wrench, readjust the angle, and then reapply force. This leads to poor work efficiency and unstable operation.

In view of the above drawbacks, the inventor proposes this disclosure based on his expert knowledge and elaborate researches in order to solve the problems of related art.

### SUMMARY OF THE DISCLOSURE

One object of this disclosure is to provide a pipe wrench that improves working efficiency and operational stability, thereby increasing convenience in use.

This disclosure is a pipe wrench including a lower jaw, an upper jaw, a pivot shaft, and a spring. The lower jaw includes a handle section and a lower clamping section connected to the handle section. A slot and an outer pivot hole communicating with the slot are defined on the lower clamping section. The lower clamping section includes a lower clamping arcuate surface formed on the top surface of the slot, and a plurality of inclined arcuate surfaces are respectively disposed on two sides of the slot. The upper jaw includes a pivot section and an upper clamping section connected to the pivot section. The pivot section includes a cam block and a stop plate. The upper clamping section includes an opening and an upper clamping arcuate surface, a plurality of pawl teeth, a stop surface, and a clearance space all disposed around the periphery of the opening. The pivot shaft is inserted in the outer pivot hole and the pivot section. The spring is disposed in the slot and elastically abuts against the stop plate.

In one embodiment of this disclosure, the lower clamping section further includes a top inclined surface connecting the lower jaw arcuate surface and each inclined arcuate surface, and the top inclined surface is disposed with an inclined angle relative to the horizontal plane.

In one embodiment of this disclosure, the lower clamping arcuate surface has a first chamfer angle, each inclined arcuate surfaces has a second chamfer angle, and the degree of the second chamfer angle is greater than that of the first chamfer angle.

In one embodiment of this disclosure, an inner pivot hole is defined on the pivot section, and the pivot shaft is inserted in the inner pivot hole.

In one embodiment of this disclosure, an embedding groove is defined on an inner wall surface of the slot of the lower clamping section, and one end of the spring abuts against the embedding groove.

In one embodiment of this disclosure, the slot extends from the top of the lower clamping section to the bottom side of the embedding groove.

In one embodiment of this disclosure, the pivot section includes a pressing wing exposed from the slot.

In one embodiment of this disclosure, the outer side of the upper clamping section is a curved surface extending to the pressing wing.

In one embodiment of this disclosure, the cam block includes a flat abutment surface and a lower convex surface connected to the flat abutment surface; the upper jaw pivots relative to the lower jaw so that the lower convex surface pushes against the inner wall of the slot, and the clearance space is enlarged.

In one embodiment of this disclosure, each of the pawl teeth includes an included angle, and the upper jaw includes a clearance angle located on one side of the pivot section, and the clearance angle is different from the included angle.

In comparison with the related art, the pipe wrench of this disclosure drives the upper clamping section to move outward when the pressing wing of the upper jaw is pressed, thereby enlarging the opening of the upper clamping section. This facilitates the placement of a workpiece between the upper clamping section and the lower clamping section, and then the workpiece is clamped by the upper jaw arcuate surface, the lower jaw arcuate surface, and the pawl teeth. In this manner, the nut is clamped between the lower jaw and the upper jaw, thereby enabling the rotational manipulation of the workpiece. Furthermore, when the pipe wrench is rotated in the opposite direction, the workpiece idly rotates within the opening of the upper clamping section to allow the handle to return to its original position to maintain a sufficient rotational angle. This enhances both the convenience and practicality of use.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 depicts a perspective exploded view of the pipe wrench of this disclosure.

FIG. 2 depicts a perspective schematic view of the pipe wrench of this disclosure.

FIG. 3 depicts a schematic front view illustrating the operation of the pipe wrench of this disclosure.

FIG. 4 is a schematic front view illustrating the idle rotation of the pipe wrench relative to the nut of this disclosure.

FIG. 5 depicts a schematic view illustrating the pressing of the pipe wrench of this disclosure.

FIG. 6 depicts a perspective exploded view of another embodiment of the pipe wrench of this disclosure.

FIG. 7 depicts a schematic front view of another embodiment of the pipe wrench of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

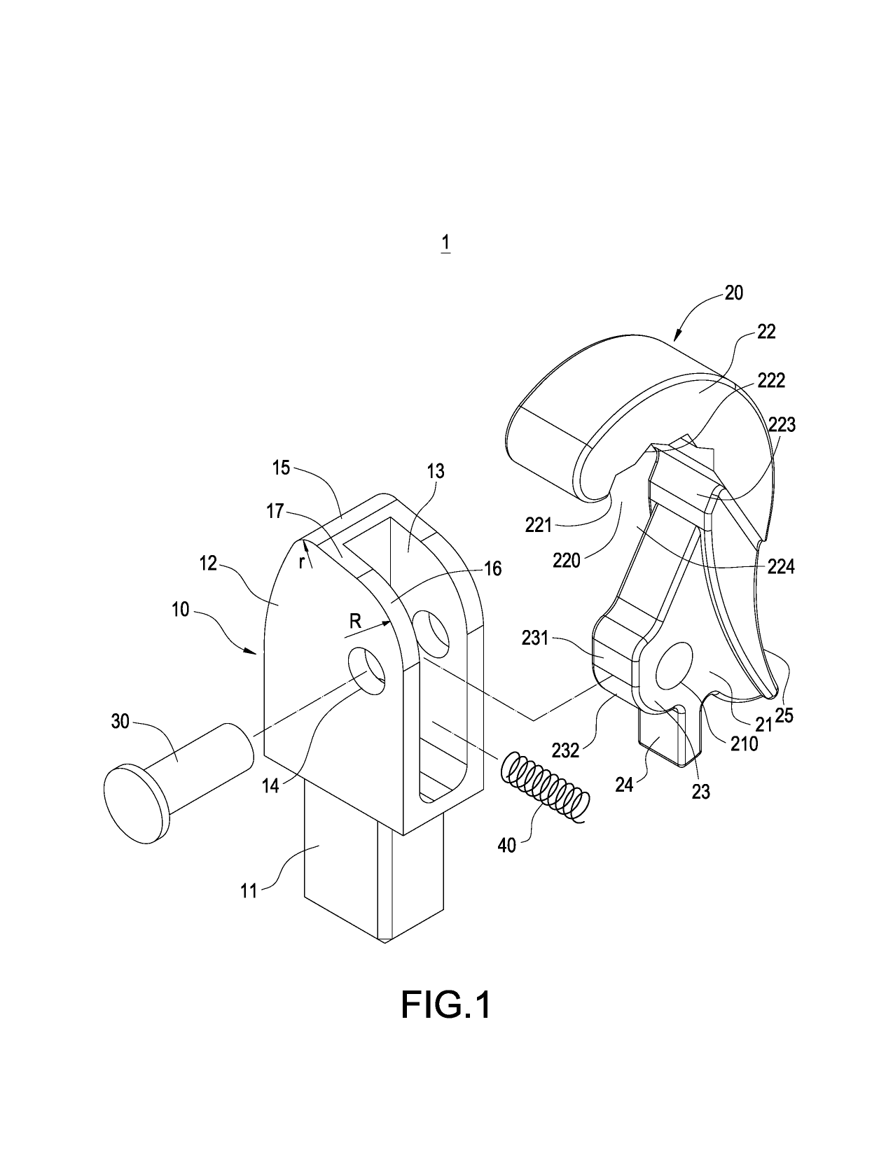

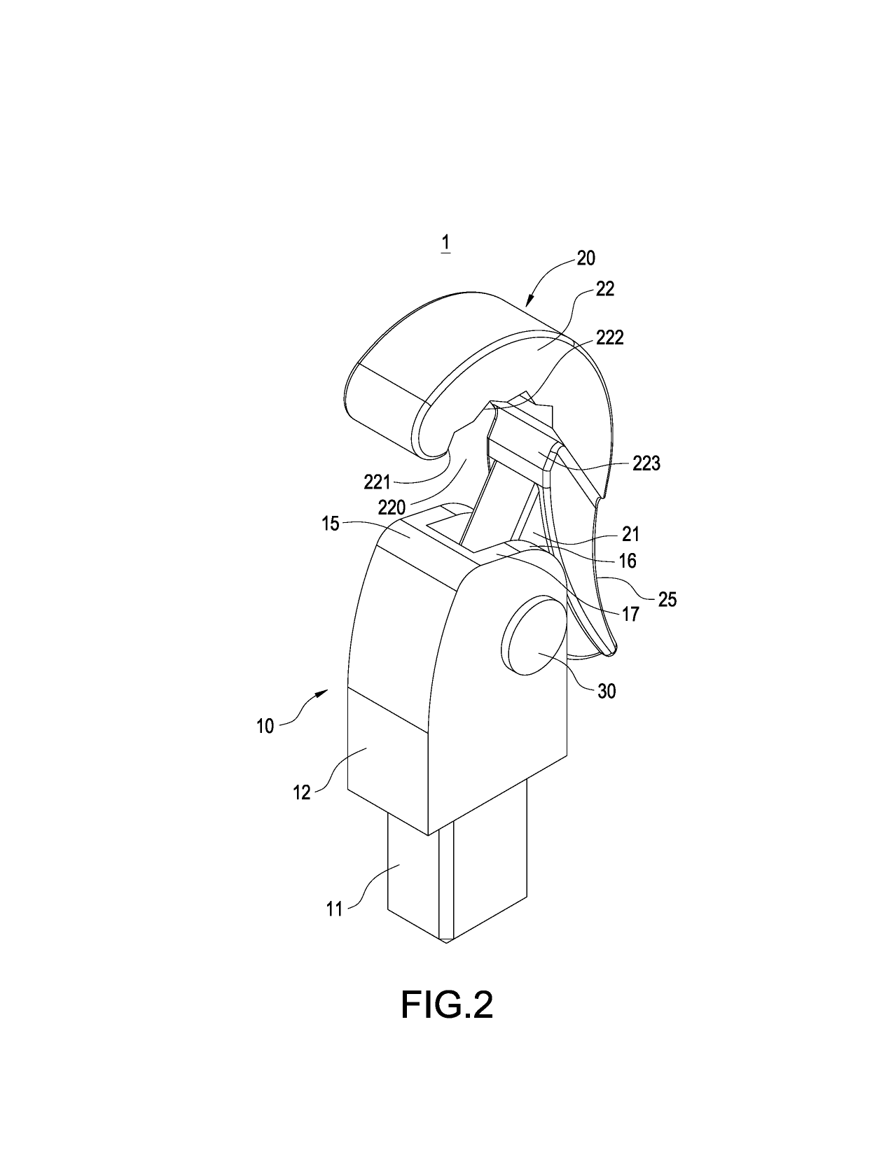

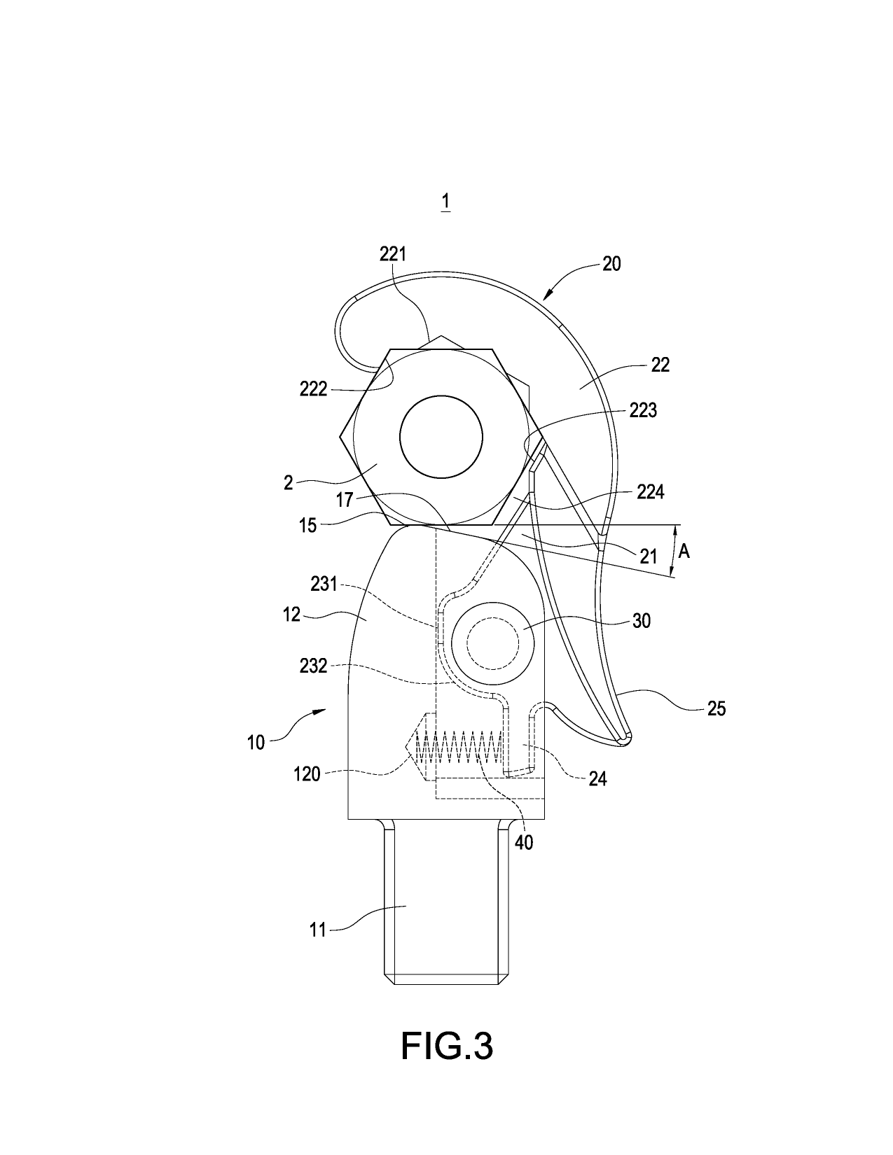

With reference to FIGS. 1 to 3, which depict a perspective exploded view, a perspective schematic view of the pipe wrench of this disclosure, and a schematic front view illustrating the operation of the pipe wrench of this disclosure, the pipe wrench 1 includes a lower jaw 10, an upper jaw 20, a pivot shaft 30, and a spring 40. The upper jaw 20 is pivotally connected to the lower jaw 10 via the pivot 30, such that the upper jaw 20 is rotatable relative to the lower jaw 10. The spring 40 is disposed on the lower jaw 10 and elastically abuts against the upper jaw 20, thereby providing a restoring force to return the upper jaw 20 to its original position. More details of the pipe wrench 1 are described as follows.

The lower jaw 10 includes a handle section 11 and a lower clamping section 12 connected to the handle section 11. A slot 13 and an outer pivot hole 14 communicating with the slot 13 are defined on the lower clamping section 12. The lower clamping section 12 includes a lower clamping arcuate surface 15 formed on the top surface of the slot 13, a plurality of inclined arcuate surfaces 16 respectively disposed on two sides of the slot 13, and a top inclined surface 17 connected with the lower jaw arcuate surface 15 and each inclined arcuate surface 16. In this embodiment, the lower clamping arcuate surface 15 includes a first chamfer angle r. Moreover, each inclined arcuate surface 16 includes a second chamfer angle R. The degree of the second chamfer angle R is greater than that of the first chamfer angle r.

The upper jaw 20 includes a pivot section 21 and an upper clamping section 22 connected to the pivot section 21. The pivot section 21 includes a cam block 23 and a stop plate 24. The upper clamping section 22 includes an opening 220 and an upper clamping arcuate surface 221, a plurality of pawl teeth 222, a stop surface 223, and a clearance space 224 all disposed around the periphery of the opening 220. Additionally, the pivot section 21 is inserted in the slot 13 so that the upper clamping arcuate surface 221 faces the lower clamping arcuate surface 15.

Specifically, the cam block 23 includes a flat abutment surface 231 and a lower convex surface 232 connected to the flat abutment surface 231. Further, when the upper jaw 20 pivots relative to the lower jaw 10 and when the lower convex surface 232 pushes against the inner wall of the slot 13, the clearance space 224 is enlarged.

In one embodiment of this disclosure, the pivot section 21 includes a pressing wing 25 exposed from the slot 13. Additionally, the outer side of the upper clamping section 22 is a curved surface and extends to the pressing wing 25.

The pivot shaft 30 is inserted in the outer pivot hole 14 and the pivot section 21. In this embodiment, an inner pivot hole 210 is defined on the pivot section 21, and the pivot shaft 30 is inserted in the inner pivot hole 210. The upper jaw 20 is connected to the lower jaw 10 through the pivot 30 to perform a pivoting motion.

Furthermore, the spring 40 is disposed in the slot 13 and elastically abuts against the stop plate 24. Additionally, an embedding groove 120 is defined on the inner wall surface of the slot 13 of the lower clamping section 12. One end of the spring 40 presses against the embedding groove 120, and the other end of the spring 40 abuts against the pivot section 21, thereby providing the restoring force required for the upper jaw 20 to return to its original position. In this embodiment, the slot 13 is a semi-open slot that extends from the top of the lower clamping section 12 to the bottom side of the embedding groove 120.

It should be noted that the pipe wrench 1 may further include an extension member (not shown in figures) sheathing the handle section 11 of the lower jaw 10, so as to increase the applied torque during use. When an external force is applied to the pressing wing 25 of the upper jaw 20, the upper clamping section 22 is driven to move outward, thereby enlarging the opening 220 of the upper clamping section 22. Furthermore, upon removal of the external force, the upper clamping section 22 may be restored to its original position by the restoring force of the spring 40, thereby reducing the size of the opening 220. Accordingly, a nut 2 of the pipe is engaged within the opening 220 and clamped by the upper clamping arcuate surface 221, the lower clamping arcuate surface 15, and the plurality of pawl teeth 222, so that the nut 2 is securely held between the lower jaw 10 and the upper jaw 20, allowing the nut 2 to be rotated accordingly. It is worth noting that the top inclined surface 17 of the lower jaw 10 is disposed with an inclination angle A relative to the horizontal plane. In the present embodiment, the inclination angle A is an acute angle. The disposition of the inclination angle A facilitates the rotation of the nut 2 on the lower jaw 10.

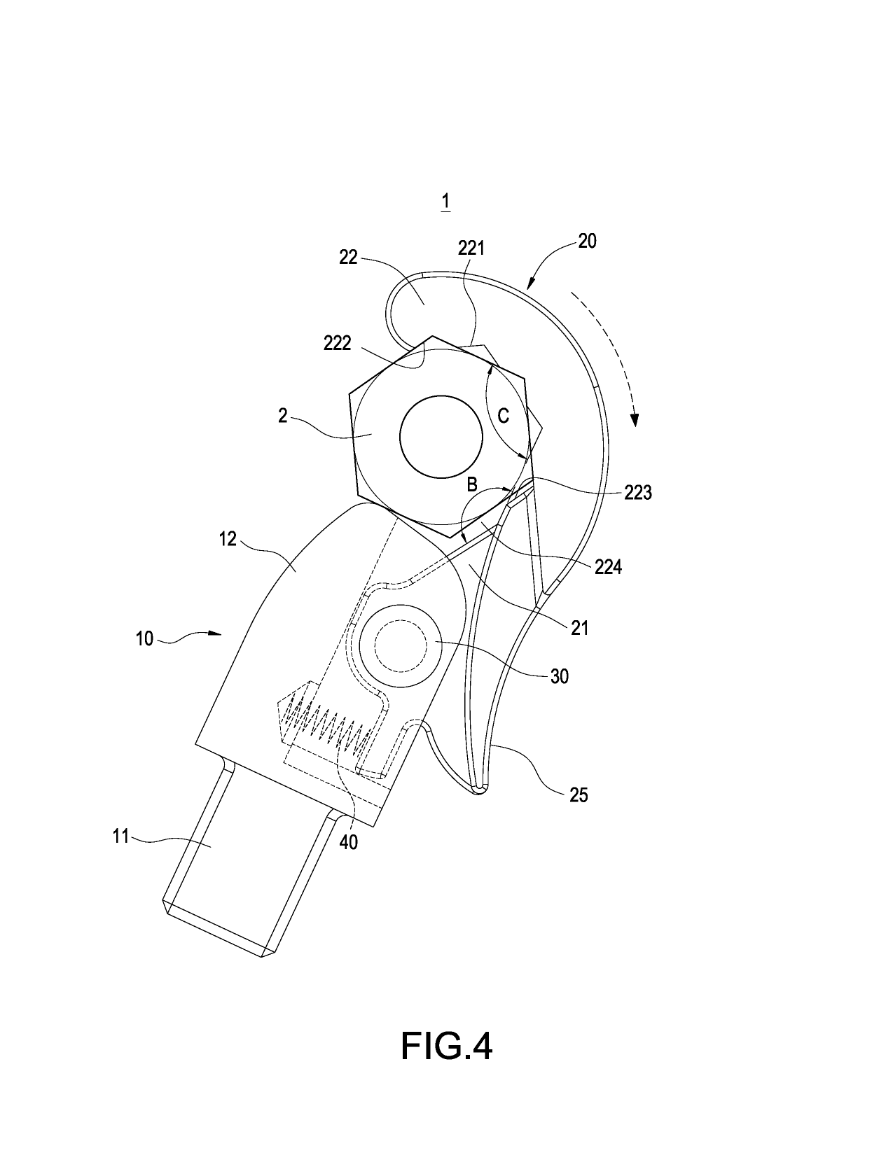

Referring also to FIG. 4, which depicts a schematic front view illustrating the idle rotation of the pipe wrench relative to the nut. After the pipe wrench 1 of this disclosure is rotated to a certain angle, it is necessary to readjust its clamping position with respect to the nut 2 so that the handle may achieve a sufficient rotational angle for effective torque output. Then, the pipe wrench 1 needs to be rotated in the opposite direction, and the nut 2 may rotate idly in the opening 220 of the upper clamping section 22; therefore, the handle returns to its original position to retain an adequate angle for continued rotation.

It is to be noted that the upper jaw 20 includes a clearance angle B located on one side of the pivot section 21. Additionally, each of the pawl teeth 222 includes an included angle C. The degree of the clearance angle B is different from the included angle C, thereby facilitating the directional switching of the rotation of the nut 2 within the opening 220.

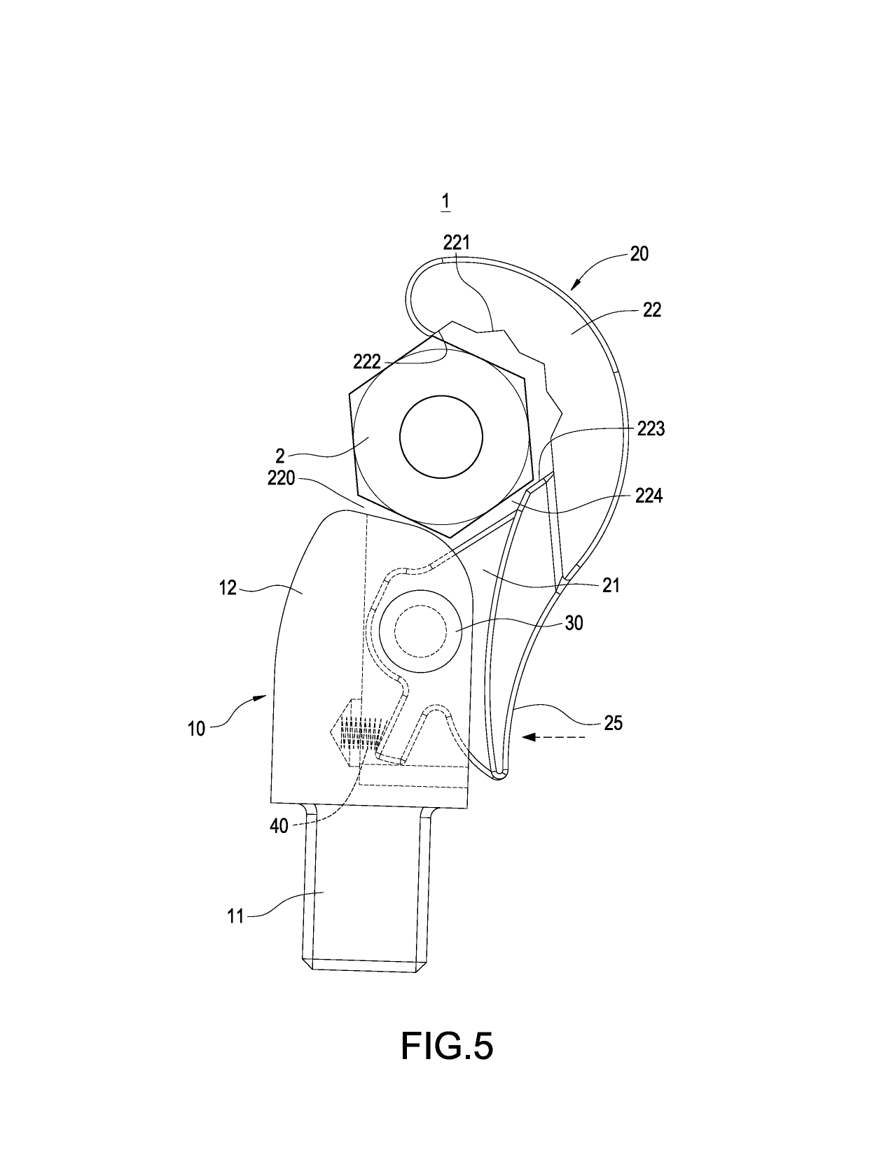

With reference to FIG. 5, which depicts a schematic view illustrating the pressing of the pipe wrench of this disclosure, when the pipe wrench 1 of this disclosure is not in use, an external force is applied to the pressing wing piece 25 of the upper jaw 20 to actuate the upper clamping section 22 to move outward, thereby enlarging the opening 220 of the upper clamping section 22. Thus, the pipe wrench 1 may be disengaged from the nut 2.

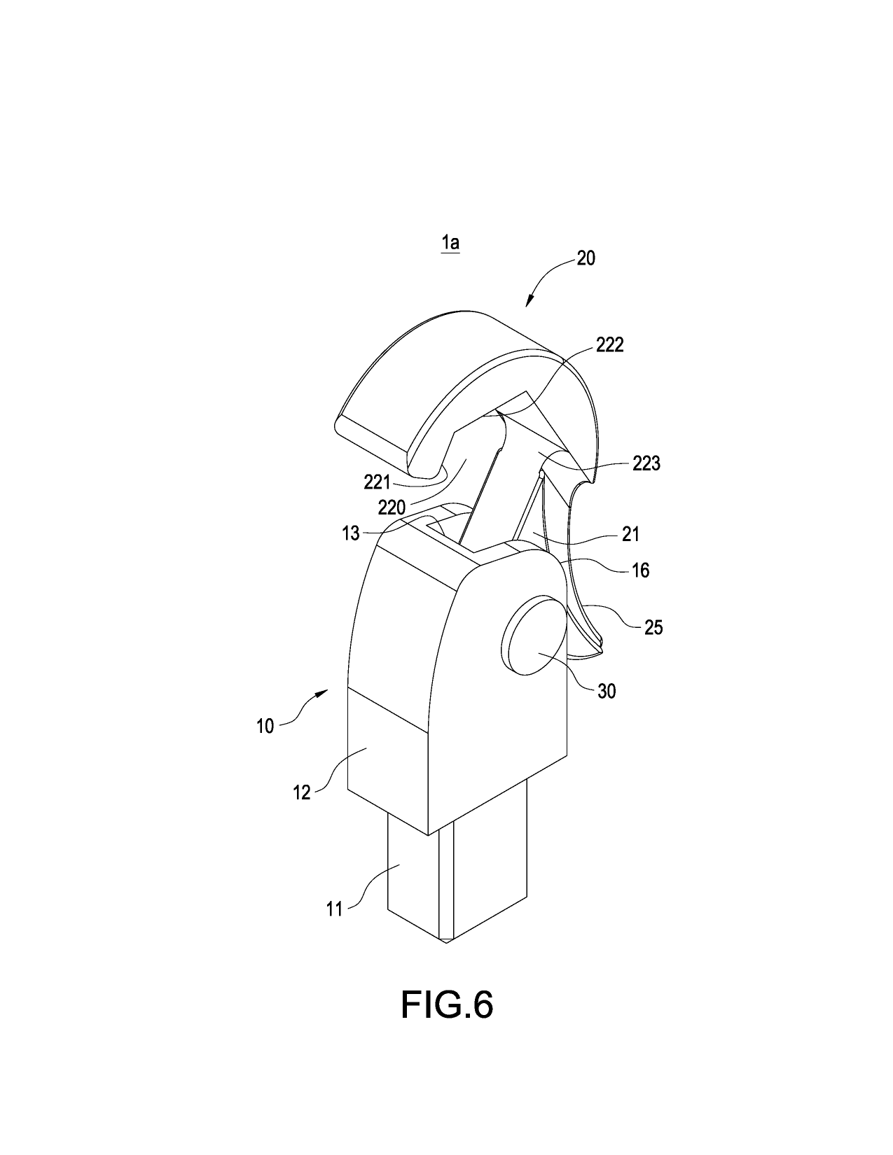

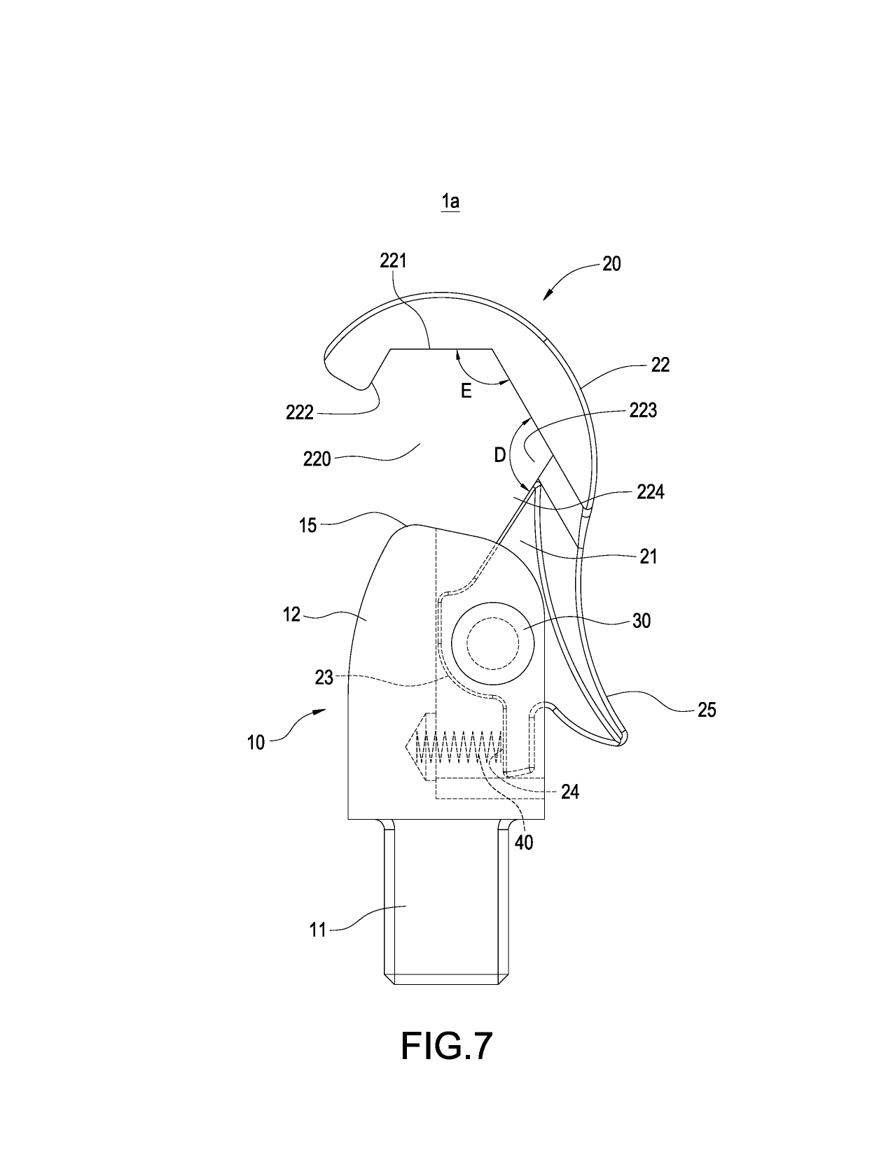

Please refer to FIGS. 6 and 7, which depict a perspective exploded schematic view and a schematic top view of another embodiment of the pipe wrench of this disclosure. This embodiment is substantially the same as the previous embodiment. The pipe wrench 1 includes a lower jaw 10, an upper jaw 20, a pivot shaft 30, and a spring 40. The lower jaw 10 includes a handle section 11 and a lower clamping section 12 connected to the handle section 11. A slot 13 is defined on the lower clamping section 12. The lower clamping section 12 includes a lower clamping arcuate surface 15 and a plurality of inclined arcuate surfaces 16. The upper jaw 20 includes a pivot section 21 and an upper clamping section 22. The pivot section 21 includes a cam block 23 and a stop plate 24. The upper clamping section 22 includes an opening 220, an upper clamping arcuate surface 221, a plurality of pawl teeth 222, a stop surface 223, and a clearance space 224. The pivot section 21 is pivotally connected to the lower clamping section 12 to make the upper curved surface 221 face the lower curved surface 15. The spring 40 elastically abuts against the stop plate 24.

Similarly, the upper jaw 20 includes a clearance angle D located on one side of the pivot section 21. Additionally, each of the pawl teeth 222 includes an included angle E. The degree of the clearance angle D is different from that of the included angle E, so that the rotation direction of the nut 2 in the opening 220 may be easily switched.

The difference of this embodiment lies in the number of pawl teeth 222 formed on the upper clamping section 22. In some embodiments, the number of pawl teeth 222 only needs to be disposed sufficiently for securely engaging the workpiece.

While this disclosure has been described by means of specific embodiments, numerous modifications and variations may be made thereto by those skilled in the art without departing from the scope and spirit of this disclosure set forth in the claims.

What is claimed is:

1. A pipe wrench, comprising:
a lower jaw, comprising a handle section and a lower clamping section connected to the handle section, wherein a slot and an outer pivot hole communicating with the slot are defined on the lower clamping section, the lower clamping section comprises a lower clamping arcuate surface disposed on a top surface of the slot, and a plurality of inclined arcuate surfaces are respectively disposed on two sides of the slot;
an upper jaw, comprising a pivot section and an upper clamping section connected to the pivot section, the pivot section comprising a cam block and a stop plate, wherein the upper clamping section comprises an opening and an upper clamping arcuate surface, a plurality of pawl teeth, a stop surface, and a clearance space all disposed around a periphery of the opening;
a pivot shaft, inserted in the outer pivot hole and the pivot section; and
a spring, disposed in the slot and elastically abutting against the stop plate.

2. The pipe wrench according to claim 1, wherein the lower clamping section further comprises a top inclined surface connected with the lower jaw arcuate surface and each inclined arcuate surface, and the top inclined surface is disposed with an inclined angle relative to a horizontal plane.

3. The pipe wrench according to claim 1, wherein the lower clamping arcuate surface comprises a first chamfer angle, each inclined arcuate surface comprises a second chamfer angle, and the second chamfer angle is greater than the first chamfer angle.

4. The pipe wrench according to claim 1, wherein an inner pivot hole is defined on the pivot section, and the pivot shaft is inserted in the inner pivot hole.

5. The pipe wrench according to claim 1, wherein an embedding groove is defined on an inner wall surface of the slot of the lower clamping section, and one end of the spring abuts against the embedding groove.

6. The pipe wrench according to claim 5, wherein the slot extends from a top of the lower clamping section to a bottom side of the embedding groove.

7. The pipe wrench according to claim 1, wherein the pivot section comprises a pressing wing exposed from the slot.

8. The pipe wrench according to claim 7, wherein an outer side of the upper clamping section is a curved surface and extends to the pressing wing.

9. The pipe wrench according to claim 1, wherein the cam block comprises a flat abutment surface and a lower convex surface connected to the flat abutment surface; the upper jaw (20) pivots relative to the lower jaw, and the lower convex surface pushes against the inner wall of the slot, the clearance space is enlarged.

10. The pipe wrench according to claim 1, wherein each of the pawl teeth comprises an included angle, and the upper jaw comprises a clearance angle located on one side of the pivot section, and the clearance angle is different from the included angle.
